(19) United States
(12) Patent Application Publication
(10) Pub. No.: US 2011/0055888 A1
(43) Pub. Date: Mar. 3, 2011

(54) CONFIGURABLE TELEVISION BROADCAST RECEIVING SYSTEM

(75) Inventors: James Clardy, Austin, TX (US); Shree A. Dandekar, Round Rock, TX (US)

(73) Assignee: DELL PRODUCTS L.P., Round Rock, TX (US)

(21) Appl. No.: 12/550,472

(22) Filed: Aug. 31, 2009

(51) Int. Cl. H04N 7/173; H03M 1/12

(52) U.S. Cl. 725/131; 341/155

(57) ABSTRACT

A configurable television broadcast receiving system includes an analog to digital converter that receives a broadcast television (TV) signal and converts it from an analog signal to a digital signal. A communication interface receives the digital signal and communicates it to a general purpose programmable processor. The processor processes the digital signal by performing arithmetic processes to the signal to create a processed signal. A display device is communicatively coupled to the processor, receives the processed signal and displays a video rendition according to the processed signal.

### BACKGROUND

The present disclosure relates generally to information handling systems (IHSs), and more particularly to a configurable television broadcast receiving system using an IHS.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Some IHSs receive and display television (TV) signal broadcasts. The traditional hardware for accomplishing television viewing on an IHS is generally based using either fixed function application specific integrated circuits (ASIC) or programmable circuits based on fixed function application specific digital signal processors (ASDSP) devices, such as location specific demodulation hardware. This type of system does not provide flexibility to modify operation of the TV system. Additionally, this requires having a variety of hardware devices to perform operations, such as demodulation of the TV signal based on location of the IHS (e.g., U.S., Europe, Japan, etc.).

Accordingly, it would be desirable to provide an improved television broadcast receiving system.

### SUMMARY

According to one embodiment, a configurable television broadcast receiving system includes an analog to digital converter that receives a broadcast television (TV) signal and converts it from an analog signal to a digital signal. A communication interface receives the digital signal and communicates it to a general purpose programmable processor. The processor processes the digital signal by performing arithmetic processes to the signal to create a processed signal. A display device is communicatively coupled to the processor, receives the processed signal and displays a video rendition according to the processed signal.

### BRIEF DESCRIPTION OF THE DRAWINGS

FIG. 1 illustrates a block diagram of an embodiment of an information handling system (IHS) using arithmetic functions of a graphics processor for broadcast television (TV) reception and processing.

FIG. 2 illustrates a block diagram of an embodiment of system architecture using the graphics processor of the IHS of FIG. 1 for software modifiable TV reception and processing.

FIG. 3 illustrates a block diagram of an embodiment of a software implementation for TV reception and processing using the system of FIG. 2.

FIG. 4 illustrates a flow chart of an embodiment of a method for implementing TV reception and processing using the systems illustrated in FIGS. 1-3.

### DETAILED DESCRIPTION

For purposes of this disclosure, an information handling system (IHS) 100 includes any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an IHS 100 may be a personal computer, a network storage device, or any other suitable device and may vary in size, shape, performance, functionality, and price. The IHS 100 may include random access memory (RAM), one or more processing resources such as a central processing unit (CPU) or hardware or software control logic, read only memory (ROM), and/or other types of nonvolatile memory. Additional components of the IHS 100 may include one or more disk drives, one or more network ports for communicating with external devices as well as various input and output (I/O) devices, such as a keyboard, a mouse, and a video display. The IHS 100 may also include one or more buses operable to transmit communications between the various hardware components.

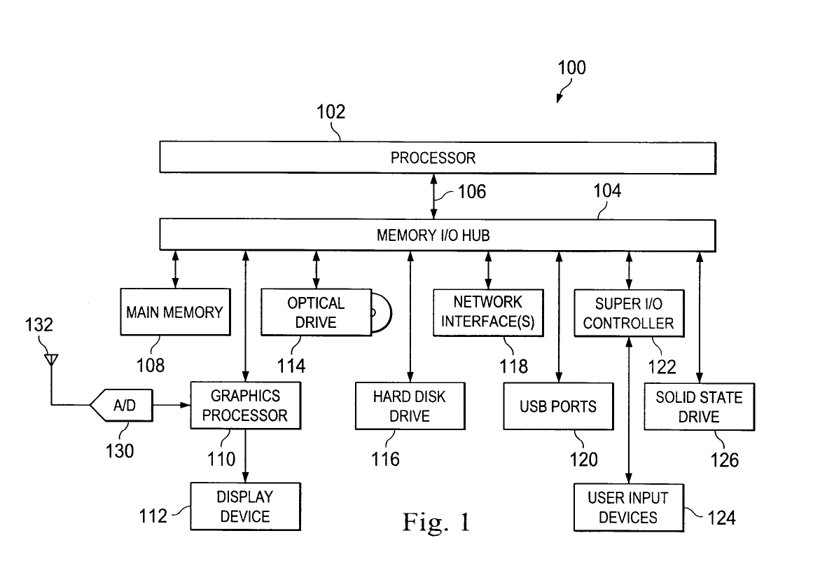

FIG. 1 is a block diagram of one IHS 100. The IHS 100 includes a processor 102 such as an Intel Pentium™ series processor or any other processor available. A memory I/O hub chipset 104 (comprising one or more integrated circuits) connects to processor 102 over a front-side bus 106. Memory I/O hub 104 provides the processor 102 with access to a variety of resources. Main memory 108 connects to memory I/O hub 104 over a memory or data bus. A graphics processor 110 also connects to memory I/O hub 104, allowing the graphics processor to communicate, e.g., with processor 102 and main memory 108. Graphics processor 110, in turn, provides display signals to a display device 112.

Other resources can also be coupled to the system through the memory I/O hub 104 using a data bus, including an optical drive 114 or other removable-media drive, one or more hard disk drives 116, one or more network interfaces 118, one or more Universal Serial Bus (USB) ports 120, and a super I/O controller 122 to provide access to user input devices 124, etc. The IHS 100 may also include a solid state drive (SSDs) 126 in place of, or in addition to main memory 108, the optical drive 114, and/or a hard disk drive 116. It is understood that any or all of the drive devices 114, 116, and 126 may be located locally with the IHS 100, located remotely from the IHS 100, and/or they may be virtual with respect to the IHS 100.

The IHS 100 includes an analog-to-digital (A/D) converter 130 communicatively coupled to the graphics processor 110. The converter 130 is an electrical device that receives television (TV) broadcast signals, amplifies them and converts them to discrete digital numbers that are proportional to the magnitude of the signal. In other words, the converter 130 includes electrical circuitry to receive the TV broadcast signals via an antenna 132, convert the TV broadcast signals to a digital/digitized format that is understandable and processable by the graphics processor 110. The graphics processor 110 performs functions, such as demodulation, on the digital signal, as is described in more detail below, to provide television program viewing on the display device 112.

Not all IHSs 100 include each of the components shown in FIG. 1, and other components not shown may exist. Furthermore, some components shown as separate may exist in an integrated package or be integrated in a common integrated circuit with other components, for example, the processor 102 and the memory I/O hub 104 can be combined together. As can be appreciated, many systems are expandable, and include or can include a variety of components, including redundant or parallel resources.

The present disclosure provides a configurable TV broadcast receiving system using an arithmetic-type processor, such as the graphics processor 110, to process the TV signals. Traditionally, IHS TV reception has been performed using either fixed function application specific integrated circuits (ASIC) or programmable circuits based on fixed function application specific digital signal processors (ASDSP) devices for the signal manipulation. However, with the continual improvement of processing power of IHSs, it is possible to allow programmable processors to perform processing of TV broadcast signals in order to view TV programs using an IHS, such as the IHS 100. Accordingly, moving the TV processing functions into software based systems in a processor reduces hardware complexity and thus, reduces costs of the systems.

Generally, multi-core central processing units (CPUs) (e.g., the processor 102) are not fast enough to demodulate digital television while performing multiple tasks, such as Internet browsing while watching TV, at an adequate level. In other words, multi-core CPUs would be strained when attempting to demodulate complex TV encoding standards, such as advanced television systems committee (ATSC) standards.

There are streaming algorithms and stages of TV signal processing (e.g., demodulation) that can be done in sequence. However, many processes for TV signal processing require parallel processing to accommodate frame-rates. Graphics processors, such as the graphics processor 110, generally provide processing power for a high ratio of parallel arithmetic operations with respect to for memory operations. Therefore, graphics processor units (e.g., processors having a large ratio of parallel arithmetic operations available with respect to memory operations available) provide adequate parallel processing power for providing a software based system for processing TV signals. Accordingly, the present disclosure replaces traditional fixed-function application specific digital signal processors (ASDSPs) with software defined radio/TV using algorithms on a graphics processor, such as a programmable general purpose GPU (GP/GPU).

Embodiments of the present disclosure thus, use software defined algorithms running on a GP/GPU to receive an intermediate form (digitized sample radio frequency (RF) broadcast TV signal) from a RF tuner; identify the waveform in the digitized signal; perform echo cancellation, noise reduction, adaptive channel correction, and demodulation; extract a video transport stream (e.g., MPEG2); optionally decrypt pay TV signals; decode the video content (e.g., MPEG2 or H.264 standards); de-interlace the video, if needed; post process the video for gamma correction, contrast enhancement, motion estimated frame-rate correction; scale the output video and/or fully up-convert result to a near high definition (HD) quality with encoding artifact removal and filtering; and output the video to the display device 112.

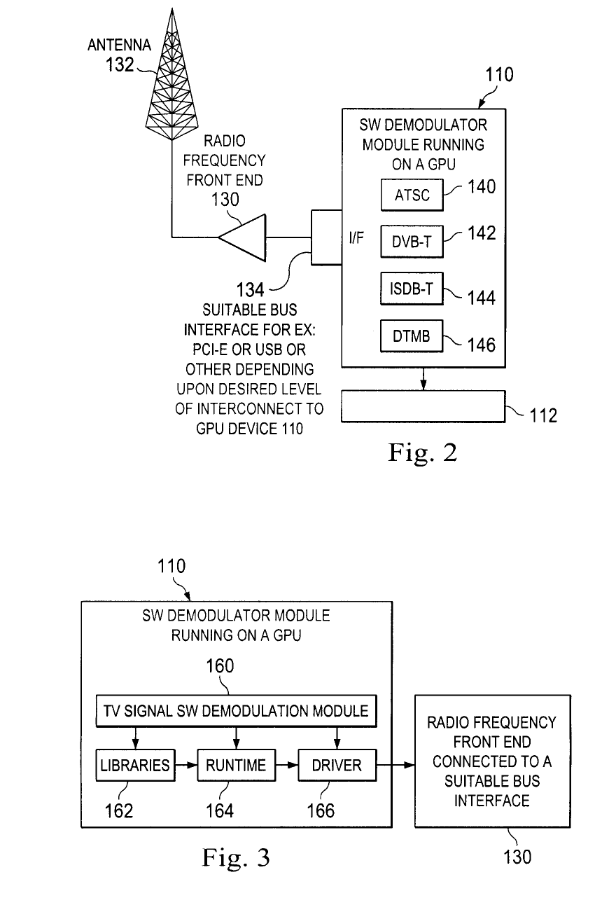

FIG. 2 illustrates a block diagram of an embodiment of a system using the graphics processor 110 for software modifiable TV reception and processing. A communication interface 134 communicates the digitized signal from the A/D converter 130 to the graphics processor 110. Examples of communication interfaces 134 that may be used to communicate the digitized signal from the A/D converter 130 to the graphics processor 10 are a universal serial bus (USB) 120 interface and a peripheral component interconnect express (PCI-E) interface. In the alternative, a dedicated communication signal system may be used to communicatively couple the A/D converter 130 to the graphics processor 110.

Because processing of the TV signals is performed by a programmable GP/GPU, the software controlling the processing may be modified to accommodate different standards of TV broadcast signals without changing the associated hardware. For example, the A/D converter 130 is designed to receive any major TV broadcast signal that the IHS is likely to receive and translate the signal to a digital signal that is readable by the graphics processor 110. Thus, software algorithms executing on the graphics processor 110 may be easily changed or may self-adapt to receive and process TV signals broadcast in standards formats, such as advanced television systems committee (ATSC) format 140, digital video broadcasting-terrestrial (DVB-T) format 142, integrated services digital broadcasting-terrestrial (ISDB-T) format 144, digital terrestrial multimedia broadcast (DTMB) format 146 or any other format.

FIG. 3 illustrates a block diagram of an embodiment of a software implementation for TV reception and processing using the graphics processor 110 of the IHS 100. A software hierarchy for the graphics processor 110 includes a TV signal demodulation module 160, a data library module 162 (e.g., a CUDA library module), a runtime module 164 (e.g., a CUDA runtime module) and a driver module 166 (e.g., a CUDA driver module). CUDA represents Compute Unified Device Architecture that is a general purpose parallel computing architecture supported by NVIDIA™ Corp. In the alternative, it is understood that other types of highly parallel processors and other programming architectures may be used with the present disclosure.

The demodulation module 160 communicates with and directs operations of the library module 162, the runtime module 164 and the driver module 166. The library module 162 communicates with the demodulation module 160 and the runtime module 164. The library module 162 includes one or more libraries (e.g., subroutines) of computer software code that provides services and allows sharing and changing of code and data. The runtime module 164 communicates with the demodulation module 160, the library module 162 and the driver module 166. The runtime module 162 includes computer software code services to provide run-time operations coupling the library module 162 with the driver module 166. The driver module 166 communicates with the demodulation module 160, the runtime module 164 and the A/D converter 130. The driver module 166 is a computer software code that allows the other modules (e.g., 160 and 164) with the hardware device (e.g., the RF front end receiver A/D converter 130) via a communication interface, such as the USB interface 134.

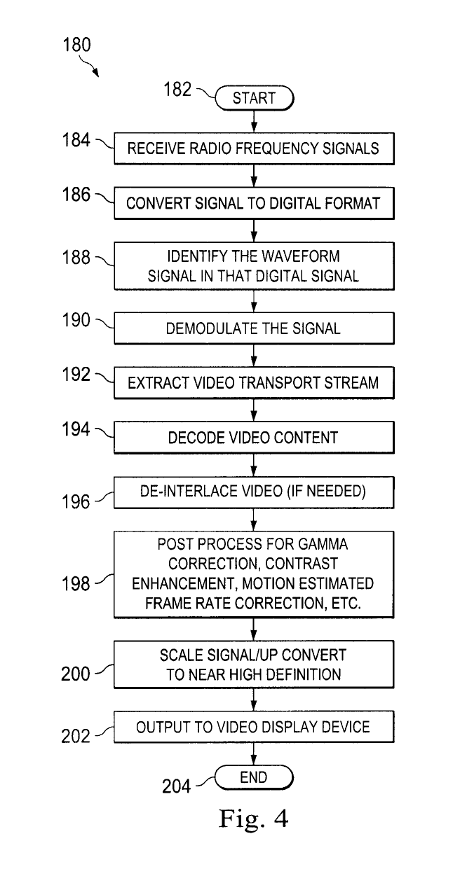

FIG. 4 illustrates a flow chart of an embodiment of a method 180 for implementing TV reception and processing using the IHS 100. The method 180 starts at block 182 where the IHS 100 is operating. The method 180 proceeds to block 184 where the IHS 100 receives RF signals, such as TV broadcast signals using the antenna 132 and the converter 130. The method 180 proceeds to block 186 where the A/D converter 130 converts the received TV broadcast signals from an analog form to a digital form and communicates the digital form of the signal to the graphics processor 110 via the communication interface 134.

The method 180 utilizes the software modules (160, 162, 164 and/or 166) to execute operations on the signal. The method 180 continues to block 188 where method identifies the waveform signal in the digitized signal. In identifying the digitized signal, the method 180 determines information about the broadcast signal, such as the transmission standard (e.g., ATSC) that was used to transmit the broadcast signal.

The method proceeds to block 190 where the method 180 demodulates the signal. Demodulation extracts the TV program information from a modulated carrier wave used to transmit the TV Broadcast signal. In an alternative embodiment, the systems of the present disclosure may amplify, perform echo cancellation, perform noise reduction, perform adaptive channel correction and/or perform other processes to the signal. The method 180 continues to block 192 where the method 180 extracts a video transport stream, such as MPEG2 data packets, from the signal. Alternatively, methods of the present disclosure may decrypt TV signals, such a pay TV signals. Method 180 next proceeds to block 194 where the method 180 decodes the video content using a decoding standard, such as MPEG2, H.264 or any other standard identified for the signal in block 188. The method 180 then proceeds to block 196 where the method de-interlaces scan lines for video portions of the decoded signal, if needed.

The method 180 then proceeds to block 198 where the method 180 performs post process operations on the signal, such as gamma correction, contrast enhancement and motion estimated frame rate correction. The method 180 then proceeds to block 200 where the method 180 scales the video output and/or up-converts the video output to a high-definition (HD) or near HD video quality and filters/removes encoding artifacts that may remain in the signal. The method 180 then proceeds to block 202 and outputs the TV program signal to the display device 112 for viewing. It is contemplated that the method allows changing channels for any signal that may be received by the IHS 100. The method 180 ends at block 204.

Accordingly, the present disclosure provides a low-cost system that maps broadcast TV to a graphics processing engine's arithmetic units. In an embodiment the system hardware architecture includes an antenna connector or antenna for receiving TV broadcast signals, a multi-format analog receiver device having a high speed digitizer to digitize the received TV broadcast signals, embedded processing to remove signal noise, a communication bus interface to communicatively couple the analog receiver to a GPU device and a display device to display the TV program. In an alternative embodiment, the antenna may be directly coupled to a graphics card having a receiver and a GPU.

It is contemplated that embodiments of the present disclosure provide a system software stack to map TV broadcast processing to a graphics processing engine's arithmetic units. Using a software system for the TV broadcast processing provides for processing of multiple TV broadcast formats used around in the world. As such, software processing algorithms vary geographically by region according to local broadcast format standards. Similarly, the software solution may be modified to include interpolation, frame rate correction, contrast enhancement, gamma correction, alpha blending 3D shading and post processing of the output TV program. Similar audio operations may be performed on the audio portion of the TV broadcast signal. The complex software algorithms of the present disclosure are performed using a GP/GPU, which provides adequate parallel processing power due to the arithmetic nature of algorithms. Using algorithms covering the DVB-T TV broadcast standard covers TV broadcasts for approximately 90 countries around the world.

In operation, an embodiment of the present disclosure provides for a use of CUDA computing architecture to demodulate and decode a received TV broadcast signal within the GPU (e.g., the graphics processor 110) so that the signal it is ready to display on a display device, such as the display device 112. As seen in FIG. 3, a set of CUDA libraries is provided to support TV signal demodulation along with a set of CUDA runtime application programming interfaces (APIs). While the embodiments discussed relate to CUDA applications, it is contemplated that other computing architectures may be used with the present disclosure. The APIs support one or more of the following functions:
a.) Receive an intermediate format (digitized radio frequency broadcast signal) from a RF tuner;
b.) Identify the waveform in that digitized signal;
c.) Demodulate it;
d.) Extract video transport stream (e.g., MPEG2);
e.) Decode the transport stream (e.g., MPEG2);
f.) De-interlace the video, if needed;
g.) Post process the signal for color correction, gamma correction, contrast enhancement, motion estimated frame-rate correction;
h.) Scale and/or up-convert the video; and
i.) Output the video to the display device.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A device comprising:
an analog to digital converter receiving a broadcast television (TV) signal and converting it from an analog signal to a digital signal;
a general purpose programmable processor;
a communication interface receiving the digital signal and communicating it to the processor, wherein the processor processes the digital signal by performing arithmetic processes to the signal to create a processed signal; and
a display device communicatively coupled to the processor and receiving the processed signal and displaying a video rendition according to the processed signal.

2. The device of claim 1, wherein the processor processes the digital signal by demodulating the signal to extract a video portion.

3. The device of claim 1, wherein the processor performs more arithmetic operations than memory operations to the processed signal.

4. The device of claim 3, wherein the processor is a graphics processor.

5. The device of claim 4, wherein the processor is a three dimensional (3D) graphics processor.

6. The device of claim 1, wherein the processor performs one of identifying, demodulating, extracting video transport stream, decoding, de-interlacing, scaling, gamma correcting, contrast enhancing, frame rate correcting and high-definition up converting to the digital signal.

7. The device of claim 1, including an audio device providing an audio rendition according to the processed signal.

8. An information handling system (IHS) comprising:
a central processing unit (CPU);
a memory coupled to the CPU; and
a television (TV) receiver system coupled to the CPU, wherein the TV receiver system includes:
an analog to digital converter receiving a broadcast television (TV) signal and converting it from an analog signal to a digital signal;
a general purpose programmable processor;
a communication interface receiving the digital signal and communicating it to the processor, wherein the processor processes the digital signal by performing arithmetic processes to the signal to create a processed signal; and
a display device communicatively coupled to the processor and receiving the processed signal and displaying a video rendition according to the processed signal.

9. The IHS of claim 8, wherein the processor processes the digital signal by demodulating the signal to extract a video portion.

10. The IHS of claim 8, wherein the processor performs more arithmetic operations than memory operations to the processed signal.

11. The IHS of claim 10, wherein the processor is a graphics processor.

12. The IHS of claim 11, wherein the processor is a three dimensional (3D) graphics processor.

13. The IHS of claim 8, wherein the processor performs one of identifying, demodulating, extracting video transport stream, decoding, de-interlacing, scaling, gamma correcting, contrast enhancing, frame rate correcting and high-definition up converting to the digital signal.

14. The IHS of claim 8, including an audio device providing an audio rendition according to the processed signal.

15. A method comprising:
receiving a broadcast television (TV) signal;
converting the TV signal from an analog signal to a digital signal;
processing the digital signal using a general purpose programmable processor, wherein the general purpose programmable processor is performing arithmetic processes to the signal to create a processed signal; and
displaying a video rendition according to the processed signal.

16. The method of claim 15, including processing the digital signal by demodulating the digital signal to extract a video portion.

17. The method of claim 15, wherein the processor is performing more arithmetic operations than memory operations to the processed signal.

18. The method of claim 17, using a graphics processor as the general purpose programmable processor.

19. The method of claim 15, including performing one of identifying, demodulating, extracting video transport stream, decoding, de-interlacing, scaling, gamma correcting, contrast enhancing, frame rate correcting and high-definition up converting to the digital signal.

20. The method of claim 15, including providing an audio rendition according to the processed signal to an audio device.
